(19) United States
(12) Patent Application Publication
(10) Pub. No.: US 2025/0287730 A1
(43) Pub. Date: Sep. 11, 2025

(54) METHOD FOR MANUFACTURING SEMICONDUCTOR DEVICE USING SEMICONDUCTOR GROWTH TEMPLATE

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,653

(22) PCT Filed: Oct. 30, 2023
(86) PCT No.: PCT/KR2023/017027

§ 371 Date: Oct. 27, 2024

(30) Foreign Application Priority Data
Oct. 31, 2022 (KR) 10-2022-0142165
Feb. 17, 2023 (KR) 10-2023-0021234
Aug. 29, 2023 (KR) 10-2023-0113956

(51) Int. Cl. H10H 20/01; C30B 25/18

(52) U.S. Cl. CPC H10H 20/019; C30B 25/186; H10H 20/012; H10H 20/021

(57) ABSTRACT

The present invention relates to a method for manufacturing a semiconductor device using a semiconductor growth template, and to a method for manufacturing a semiconductor light-emitting device or a power semiconductor device by using a semiconductor growth template including an ultra-thin type sapphire seed layer.

### TECHNICAL FIELD

The present invention relates to a method of manufacturing a semiconductor light-emitting device or a power semiconductor device using a semiconductor growth template.

### BACKGROUND ART

In general, micro-light-emitting diode (LED) displays including mini LED displays may be classified into micro-LED displays using a passive matrix (PM) driving method and micro-LED displays using an active matrix (AM) driving method.

Here, PM-driven micro LED displays typically have a sapphire support substrate, which finally remains, and use sorted thick BGR (Blue, Green, and Red) chips (with both a fully fabricated anode and cathode of the LED), which are transferred using a chip die-level process in which either horizontal chips or flip chips may generally be used.

In addition, AM-driven micro LED displays typically do not have a sapphire support substrate, which finally remains, and use unsorted thin BGR (Blue, Green, and Red) chips (with both an anode and a cathode of the LED are completed), which are transferred using a wafer-level process in which horizontal chips, flip chips, or vertical chips may all be generally utilized.

Meanwhile, as smaller compact dies (epitaxy dies or chips) are required for manufacturing mini-or micro-level semiconductor light-emitting devices, a thinner-sapphire forming process technology is required.

That is, in order to reduce a chip die size in terms of an aspect ratio, it is essential to reduce a thickness of the final growth substrate (or support substrate) sapphire. However, a current thickness of the growth substrate (or support substrate) sapphire is limited to about 80 μm to about 70 μm, and when the thickness is reduced to 50 μm or less, the issue of sapphire substrate breakage occurs.

For this reason, there was an attempt to mold the first growth substrate sapphire thinly and then grow a Group III nitride semiconductor, but a problem occurred in which a die or wafer was also deformed and damaged during a forming or transferring process due to thermo-mechanical induced stress caused by differences in lattice constant (LC) and coefficient of thermal expansion (CTE) between the sapphire growth substrate and the Group III nitride semiconductor.

Meanwhile, in a power semiconductor device (high electron mobility transistor (HEMT) having a lateral channel structure based on a technology for directly growing gallium nitride (GaN) materials on the conventional silicon (Si) single crystal growth substrate wafer, in order for the corresponding device to be operated stably at high temperatures with high voltage and/or high-speed switching capabilities, a design that suppresses the leakage current of a power semiconductor device through high-quality epitaxy thin film growth technology with high breakdown voltage and high reliability characteristics is essential.

To this end, conventional Group III nitride semiconductor thin film materials and power semiconductor device structures thereof have a structure in which 1) a silicon (Si) single crystal growth substrate having high electrical resistance characteristics is provided, and 2) a melt-back etching prevention layer, 3) a crack-preventing compressive stress layer, and 4) a power semiconductor active layer are sequentially grown, stacked, and formed, wherein the melt-back etching prevention layer includes a surface layer of a silicon (Si) single crystal growth substrate wafer and an aluminum nitride (AlN) material (nitride or nitride oxide including an aluminum (Al) composition) for suppressing a melt-back etching phenomenon through a reaction at a high temperature, the crack-preventing compressive stress layer includes an aluminum gallium nitride (AlGaN) material (Group III nitride including an aluminum (Al) or gallium (Ga) composition), and the power semiconductor active layer includes a gallium nitride (GaN) material (Group III nitride including a gallium (Ga) composition).

A power semiconductor active layer (HEMT) with a lateral channel structure including the gallium nitride (GaN) material described above is typically formed by stacking four areas: 1) a gallium nitride (GaN) buffer layer, 2) a gallium nitride (GaN) channel layer (lateral transistor), 3) an aluminum gallium nitride (AlGaN) barrier layer, and 4) a capping passivation layer (depletion mode) or a p-type nitride semiconductor layer (enhancement mode).

That is, in the conventional Group III nitride power semiconductor HEMT device structure in which a gallium nitride (GaN) material is grown directly on a silicon (Si) single crystal growth substrate wafer, a high-resistance silicon (Si) single crystal growth substrate wafer needs to be applied below a gallium nitride (GaN) channel layer along with the formation of a high-resistance gallium nitride (GaN) buffer layer, but there are the following problems.

First, in the conventional Group III nitride (gallium nitride (GaN) material-based) power semiconductor HEMT device structure, a process of directly growing a gallium nitride (GaN) material-based single crystal thin film and a power semiconductor device structure on a silicon (Si) single crystal wafer for a Group III nitride power semiconductor growth substrate is performed using metal organic chemical vapor deposition (MOCVD) equipment. In this case, a process of growing a gallium nitride (GaN) material-based single crystal thin film including gallium (Ga) atoms (deposition) is basically performed at a high temperature of about 1,000° C. and a reducing atmosphere (H₂, H+, NH₃, and radical ions). In this case, a melt-back etching prevention film area is absolutely required to block an active Si-Ga metallic eutectic reaction from occurring with relatively small energy between a surface layer of a silicon (Si) single crystal wafer and gallium (Ga) atoms.

The melt-back etching prevention film area typically has a thickness of about 100 nm and representatively includes an aluminum nitride (AlN) material layer grown through an in-situ process in a MOCVD chamber. In addition, an aluminum nitride (AlN) or aluminum oxide (AlNO) material layer may also be deposited on a silicon (Si) single crystal wafer for a Group 3 nitride power semiconductor growth substrate through an ex-situ process using other external deposition process equipment (sputtering, pulsed laser deposition (PLD), or atomic laser deposition (ALD) equipment) before the Si single crystal wafer is loaded into the MOCVD chamber.

However, when forming a melt-back etching prevention film area formed with the above-described aluminum nitride (AlN) material layer on a silicon (Si) single crystal wafer for a growth substrate with electrically high resistance characteristics, there is a problem that, during aluminum nitride (AlN) growth, although the level of damage to a surface of a silicon (Si) growth substrate is less, an Si-Al metallic process reaction occurs entirely or locally on the surface of the silicon (Si) growth substrate to form a conductive interface material layer, which still causes a deterioration in crystal quality of a gallium nitride (GaN) material grown in a continuous process. In addition, there is a problem that the crystal quality deteriorates (crystallinity decreases) due to the formation of a conductive interface material (disordered SiAlN) caused by the damage to the surface of the silicon (Si) growth substrate, and as a result, a leakage current increases due to an increase in density of dislocations, which are major crystal defects, thereby ultimately accelerating an insulation breakdown phenomenon.

Second, in the conventional Group III nitride (GaN material-based) power semiconductor HEMT device structure described above, when a material is grown (or deposited), a process should be performed in consideration of an LC and a CTE which are material-specific values between different types of materials. However, typically, when differences in LC and CTE between two materials are large, micro- or macro-cracks are generated in a grown or deposited material thin film or crystal quality deteriorates due to structural and thermal-mechanical stress during or after a growth (deposition) process. In particular, when a gallium nitride (GaN) material or an aluminum nitride (AlN) material is grown (or deposited) directly on an Si single crystal wafer for a Group III nitride power semiconductor growth substrate, since strong tensile stress is generated in terms of the CTE and/or LC, not only a crack phenomenon may be easily observed, but also, the gallium nitride (GaN) material or aluminum nitride (AlN) material may be grown to a certain thickness or more to implement an device with a high breakdown voltage and high reliability. However, a thickness of a Group III nitride power semiconductor device structure cannot be increased due to tensile stress.

Although various technologies have been devised as a way to relieve tensile stress or suppress cracks as described above, as a way to introduce materials and processes that artificially generate compressive stress to compensate for or buffer tensile stress, a crack prevention compressive stress layer that suppresses a crack phenomenon is being introduced and used by stacking an aluminum gallium nitride (AlGaN) material including an aluminum (Al) or gallium (Ga) composition on the melt-back etching prevention film area described above in an already known multilayer structure.

However, the crack prevention compressive stress layer of the conventional Group III nitride (GaN material-based) power semiconductor HEMT device structure described above has a problem that, when an aluminum gallium nitride (AlGaN) material with a high aluminum (Al) ratio is formed, a thick layer with high quality is difficult to grow, and a decrease in crystal quality causes dislocations, which promotes an increase in leakage current.

Third, in the conventional Group III nitride (GaN material-based) power semiconductor HEMT device structure, in order to suppress a leakage current below a gallium nitride (GaN) channel layer, a gallium nitride (GaN) buffer layer heavily doped with impurities such as iron (Fe) or carbon (C) to have high resistance is typically formed.

However, according to the conventional Group III nitride (GaN material) power semiconductor HEMT device structure, there is a problem in that the crystal quality of the gallium nitride (GaN) material greatly deteriorates due to excessive doping of impurities such as iron (Fe) or carbon (C), and an increase in density of fatal crystal defects, that is, dislocations, promotes an increase in leakage current. In addition, there is a problem that, due to the gallium nitride (GaN) buffer layer having low crystal quality, the gallium nitride (GaN) channel layer and aluminum gallium nitride (AlGaN) barrier layer grown thereon through a continuous process also have low crystal quality.

Accordingly, a GaN-on-sapphire method, which has the next best crystal quality after a power semiconductor device manufactured using a GaN-on-GaN method, is widely used to improve crystal quality, and the epitaxy deposition technology in this method has already been developed and matured. However, the only drawback of the GaN-on-sapphire method is that the heat dissipation capacity of sapphire is poor, and thus the GaN-on-sapphire method has a limitation in application to high-power products.

To overcome this limitation, high-power products have been developed using silicon carbide (SiC) and silicon (Si) growth substrates with high heat dissipation performance, but are inferior to epitaxy products grown on sapphire growth substrates in terms of performance, crystal quality, defects, and costs.

Furthermore, in order to improve the heat dissipation performance of a power semiconductor device, when a growth substrate is completely removed and a high heat dissipation support substrate is bonded, there is an advantage in that the heat dissipation performance of the power semiconductor device may be greatly improved. However, there is a problem that, during a process of removing the growth substrate and bonding the high heat dissipation support substrate, the long-term reliability of the power semiconductor device is adversely affected by thermo-mechanical shock or material diffusion.

### DISCLOSURE

### Technical Problem

The present invention is directed to solving the above-described conventional problems and providing a method of manufacturing a semiconductor light-emitting device using a semiconductor growth template in which a semiconductor light-emitting device having a thinner thickness may be manufactured using a semiconductor growth template including an ultra-thin type sapphire seed layer.

The present invention is also directed to solving the above-described conventional problems and providing a method of manufacturing a power semiconductor device using a semiconductor growth template in which a power semiconductor device is manufactured using a semiconductor growth template including an ultra-thin type sapphire seed layer, thereby significantly reducing defects in a power semiconductor device to which a high heat dissipation support substrate is bonded and manufacturing a high-performance power semiconductor device.

### Technical Solution

The object of the present invention is achieved by a method of manufacturing a semiconductor light-emitting device using a semiconductor growth template, the method including a preparing operation of preparing a first growth substrate and a second growth substrate, a bonding operation of bonding the first growth substrate and the second growth substrate through a bonding layer, a forming operation of forming the second growth substrate into an ultra-thin type such that the second growth substrate functions as a seed layer and manufacturing a template, and an device forming operation of forming a semiconductor light-emitting device on the second growth substrate of the template.

In addition, the first growth substrate and the second growth substrate may be sapphire substrates.

In addition, a thickness of the formed second growth substrate may be less than 50 μm.

In addition, a sacrificial separation layer may be disposed on at least one of an upper surface of the first growth substrate and a lower surface of the second growth substrate.

In addition, the device forming operation may include a first operation of growing a light-emitting portion on the second growth substrate formed into the ultra-thin type, a second operation of performing a fab process on the grown light-emitting portion and forming the semiconductor light-emitting device on the second growth substrate, and a third operation of sawing the second growth substrate to divide the semiconductor light-emitting device into die units and separating the bonding layer and the first growth substrate from a sacrificial separation layer disposed on a lower surface of the second growth substrate.

In addition, the device forming operation may further include a fourth operation of removing the sacrificial separation layer disposed on the lower surface of the second growth substrate.

In addition, the device forming operation may further include a fourth operation of forming a surface texture pattern on the sacrificial separation layer disposed on the lower surface of the second growth substrate.

In addition, in the third operation, a crack may be generated on a surface of or inside the second growth substrate through a laser beam and then may propagate so that the semiconductor light-emitting device is sawn and divided into the die units.

The object of the present invention is achieved by a method of manufacturing a power semiconductor device using a semiconductor growth template, the method including a preparing operation of preparing a first growth substrate and a second growth substrate, a bonding operation of bonding the first growth substrate and the second growth substrate through a bonding layer, a forming operation of forming the second growth substrate into an ultra-thin type such that the second growth substrate functions as a seed layer and manufacturing a template, and an device forming operation of forming a power semiconductor device on the second growth substrate of the template.

In addition, the first growth substrate and the second growth substrate may be sapphire substrates.

In addition, a thickness of the formed second growth substrate may be less than 50 μm.

In addition, a sacrificial separation layer may be disposed on at least one of an upper surface of the first growth substrate and a lower surface of the second growth substrate.

In addition., in the device forming operation, the bonding layer and the first growth substrate may be separated from the second growth substrate, and the second growth substrate and a support substrate may be bonded through the bonding layer.

In addition, a reinforcement layer which reinforces bonding strength of the adhesive layer and induces compressive stress may be disposed on at least one of an upper surface and a lower surface of the bonding layer.

In addition, wherein, in the device forming operation, a via hole may be formed in the second growth substrate, and then a heat dissipation portion may be formed in the via hole.

In addition, the heat dissipation portion may be connected to an electrode of the power semiconductor device through a connection portion.

In addition, the device forming operation may include a first operation of bonding the second growth substrate, which is formed into the ultra-thin type, and a support substrate through a bonding layer, a second operation of separating the bonding layer and the first growth substrate from a sacrificial separation layer disposed on a lower surface of the second growth substrate, a third operation of growing a semiconductor layer on the sacrificial separation layer, or when the sacrificial separation layer is removed, growing the semiconductor layer on the second growth substrate, and a fourth operation of performing a fab process on the grown semiconductor layer and forming the power semiconductor device on the second growth substrate.

In addition, the device forming operation may include a first operation of growing a semiconductor layer on the second growth substrate formed into the ultra-thin type, a second operation of performing a fab process on the grown semiconductor layer and forming the power semiconductor device on the second growth substrate, and a third operation of bonding an upper portion of the power semiconductor device and a first temporary substrate through an adhesive layer, a fourth operation of separating the bonding layer and the first growth substrate from a sacrificial separation layer disposed on a lower surface of the second growth substrate, a fifth operation of bonding the sacrificial separation layer and a support substrate through a first bonding layer, and a sixth operation of separating the adhesive layer and the first temporary substrate from an upper portion of the power semiconductor device.

In addition, in the fifth operation, the sacrificial separation layer and the support substrate may be bonded through the bonding layer, and the support substrate and a second temporary substrate may be bonded through a lower bonding layer. In the sixth operation, the adhesive layer and the first temporary substrate may be separated from the upper portion of the power semiconductor device, and then the second temporary substrate may be separated from the lower bonding layer.

In addition, in the third operation, a protective layer may be formed on the upper portion of the power semiconductor device, and then the protective layer and the first temporary substrate may be bonded through the adhesive layer.

In addition, in the fifth operation, a surface roughness pattern may be formed on the sacrificial separation layer, and then the sacrificial separation layer and the support substrate may be bonded through the bonding layer.

In addition, the semiconductor layer may include at least one of a buffer layer, a channel layer, and a barrier layer.

### Advantageous Effects

According to the present invention, there is an effect of being able to manufacture a semiconductor light-emitting device or die (epitaxy die or chip) having a thickness of less than 50 μm.

In addition, there is an effect in which a power semiconductor device is manufactured using a semiconductor growth template including an ultra-thin type sapphire seed layer, thereby considerably reducing defects in a power semiconductor device to which a high heat dissipation support substrate is bonded and manufacturing a high-performance power semiconductor device.

In addition, according to the present invention, it is possible to provide a semiconductor growth template capable of completely relieving thermo-mechanical induced stress caused by differences in lattice constant (LC) and coefficient of thermal expansion (CTE) between a thin sapphire growth substrate and a Group III nitride semiconductor when the Group III nitride semiconductor is grown, thereby significantly reducing the defect rate of a manufactured power semiconductor device.

Meanwhile, the effects of the present invention are not limited to the above-described effects, and various effects may be included within the range apparent to those skilled in the art from contents to be described below.

### DESCRIPTION OF DRAWINGS

FIG. 1 is a flowchart of a method of manufacturing a semiconductor light-emitting device using a semiconductor growth template according to one embodiment of the present invention.

FIG. 2 is a flowchart of an device forming operation of the method of manufacturing a semiconductor light-emitting device using a semiconductor growth template according to one embodiment of the present invention.

FIG. 3 illustrates a process of manufacturing a template through the method of manufacturing a semiconductor light-emitting device using a semiconductor growth template according to one embodiment of the present invention.

FIG. 4 illustrates a process of forming a semiconductor light-emitting device on the template in the method of manufacturing a semiconductor light-emitting device using a semiconductor growth template according to one embodiment of the present invention.

FIG. 5 illustrates a process in which the semiconductor light-emitting device is sawn and separated into die units using a laser beam in a third operation of the method of manufacturing a semiconductor light-emitting device using a semiconductor growth template according to one embodiment of the present invention.

FIG. 6 illustrates a surface texture pattern being formed on a sacrificial separation layer in a fourth operation of the method of manufacturing a semiconductor light-emitting device using a semiconductor growth template to one embodiment of the present invention.

FIG. 7 is a flowchart of a method of manufacturing a power semiconductor device using a semiconductor growth template according to first to third embodiments of the present invention.

FIG. 8 illustrates a process of manufacturing a template through the method of manufacturing a power semiconductor device using a semiconductor growth template according to the first to third embodiments of the present invention.

FIG. 9 is a flowchart of an device forming operation of the method of manufacturing a power semiconductor device using a semiconductor growth template according to the first embodiment of the present invention.

FIG. 10 illustrates a process of forming a power semiconductor device on the template in the method of manufacturing a power semiconductor device using a semiconductor growth template according to the first embodiment of the present invention.

FIG. 11 is a flowchart of an device forming operation of the method of manufacturing a power semiconductor device using a semiconductor growth template according to the second embodiment of the present invention.

FIG. 12 illustrates a process of forming a power semiconductor device on a template in the method of manufacturing a power semiconductor device using a semiconductor growth template according to the second embodiment of the present invention.

FIG. 13 illustrates a surface roughness pattern being formed on a sacrificial separation layer in the method of manufacturing a power semiconductor device using a semiconductor growth template to the second or third embodiment of the present invention.

FIG. 14 is a flowchart of an device forming operation of the method of manufacturing a power semiconductor device using a semiconductor growth template according to the third embodiment of the present invention.

FIG. 15 illustrates a process of forming a power semiconductor device on a template in the method of manufacturing a power semiconductor device using a semiconductor growth template according to the third embodiment of the present invention.

FIGS. 16 and 17 illustrate a heat dissipation portion being formed on a second growth substrate in the method of manufacturing a power semiconductor device using a semiconductor growth template according to the first to third embodiments of the present invention.

FIGS. 18 and 19 illustrate a heat dissipation portion and a connection portion being formed on the second growth substrate in the method of manufacturing a power semiconductor device using a semiconductor growth template according to the first to third embodiments of the present invention.

### MODES OF THE INVENTION

Hereinafter, some embodiments of the present invention will be described in detail with the accompanying exemplary drawings. When reference numerals refer to components of each drawing, although the same components are illustrated in different drawings, the same components are referred to by the same reference numerals as much as possible.

Further, in describing the present invention, a detailed description of related known configurations and functions will be omitted when it is determined that it may obscure understanding of the embodiments of the present invention.

In addition, in describing components of the embodiment of the present invention, terms such as first, second, A, B, (a), and (b) may be used. The terms are used to distinguish one component from another component. However, the nature, order, sequence, or the like of components is not limited by these terms.

Hereinafter, a method S100a of manufacturing a semiconductor light-emitting device using a semiconductor growth template according to one embodiment of the present invention will be described in detail with reference to the accompanying drawings.

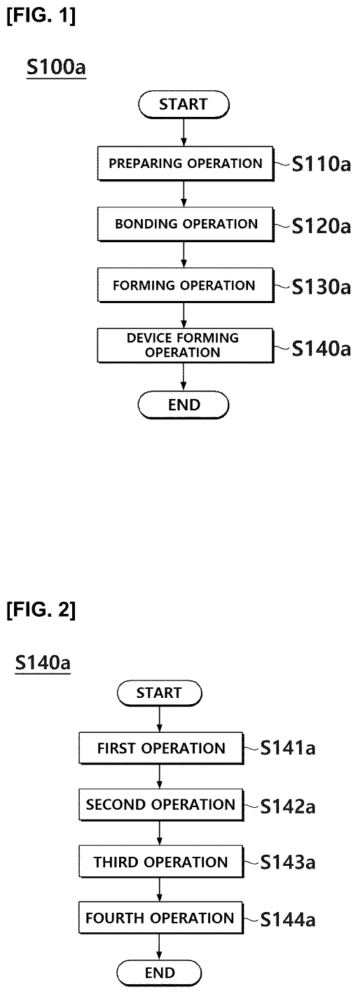

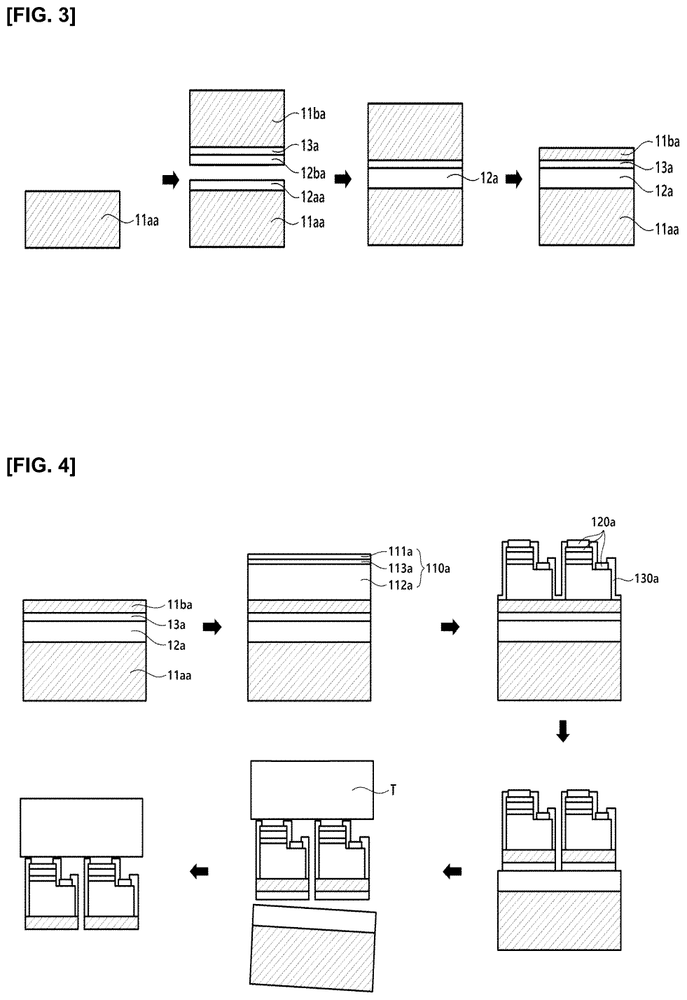

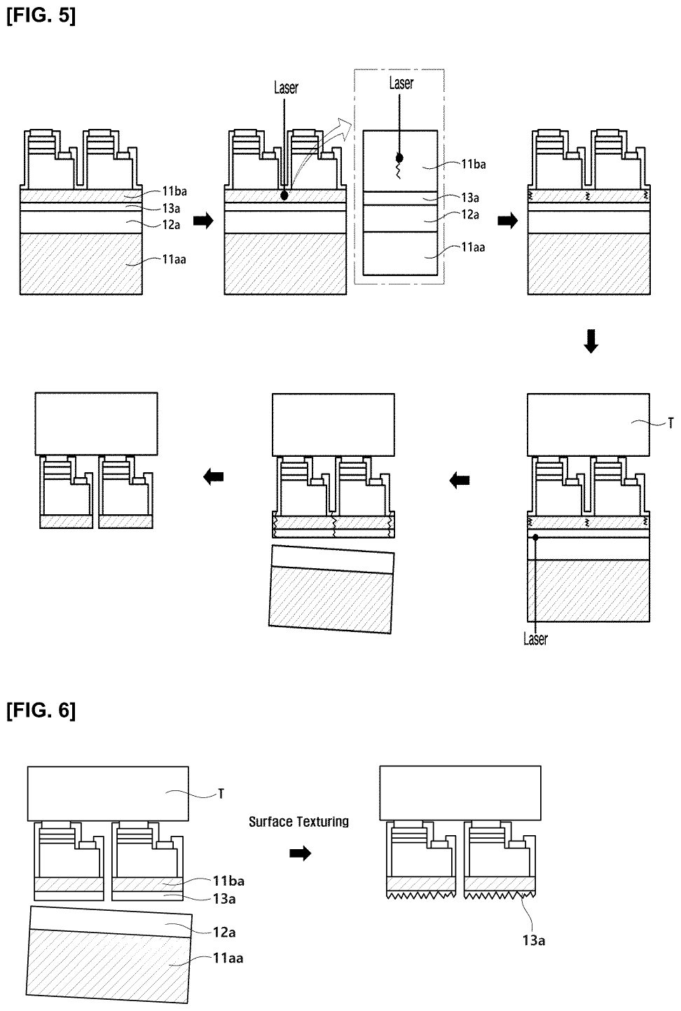

FIG. 1 is a flowchart of the method of manufacturing a semiconductor light-emitting device using a semiconductor growth template according to one embodiment of the present invention. FIG. 2 is a flowchart of an device forming operation of the method of manufacturing a semiconductor light-emitting device using a semiconductor growth template according to one embodiment of the present invention. FIG. 3 illustrates a process of manufacturing a template through the method of manufacturing a semiconductor light-emitting device using a semiconductor growth template according to one embodiment of the present invention. FIG. 4 illustrates a process of forming a semiconductor light-emitting device on the template in the method of manufacturing a semiconductor light-emitting device using a semiconductor growth template according to one embodiment of the present invention. FIG. 5 illustrates a process in which the semiconductor light-emitting device is sawn and separated into die units using a laser beam in a third operation of the method of manufacturing a semiconductor light-emitting device using a semiconductor growth template according to one embodiment of the present invention. FIG. 6 illustrates a surface texture pattern being formed on a sacrificial separation layer in a fourth operation of the method of manufacturing a semiconductor light-emitting device using a semiconductor growth template to one embodiment of the present invention.

As shown in FIGS. 1 and 3, the method S100a of manufacturing a semiconductor light-emitting device using a semiconductor growth template according to one embodiment of the present invention is for manufacturing a small die (epitaxy die or chip) having a thickness of less than 50 μm, which has been previously impossible to manufacture, and includes a preparing operation S110a, a bonding operation S120a, a forming operation S130a, and an device forming operation S140a.

The preparing operation S110a is an operation of providing a first growth substrate 11aa and a second growth substrate 11ba.

Here, the first growth substrate 11aa and the second growth substrate 11ba may be provided as sapphire substrates. The sapphire substrates are optically transparent and high temperature-heat resistant substrates that may (theoretically) transmit 100% of a laser beam (single wavelength light) without absorption in a laser lift-off (LLO) process, and may be formed of α-phase Al₂O₃ sapphire (including ScAlMgO₄). In addition, it is preferable that the growth substrate has a protrusion shape that is patterned regularly or irregularly in various dimensions (sizes and shapes) in microscale or nanoscale to minimize crystal defects in a Group III nitride semiconductor epitaxy thin film grown thereon.

In addition, as the first growth substrate 11aa serves as a carrier sapphire substrate, although the first growth substrate 11aa does not require relatively high quality as compared to the second growth substrate 11ba, the first growth substrate 11aa is required to be optically transparent by both surfaces being polished.

The second growth substrate 11ba serves as a growth sapphire substrate and is formed into an ultra-thin type in a subsequent operation to serve as a seed layer. The second growth substrate 11ba should be positioned such that a surface on which a Group III nitride semiconductor such as gallium nitride (GaN) is grown becomes an upper surface and is required to be optically transparent by both surfaces being polished to high quality.

The bonding operation S120a is an operation of bonding the first growth substrate 11aa and the second growth substrate 11ba through a bonding layer 12a.

More specifically, the bonding layer 12a may be formed on an upper surface of the first growth substrate 11aa or a lower surface of the second growth substrate 11ba to bond the first growth substrate 11aa and the second growth substrate 11ba. Preferably, after a first bonding layer 12aa is formed on the upper surface of the first growth substrate 11aa and a second bonding layer 12ba is formed on the lower surface of the second growth substrate 11ba, the first bonding layer 12aa and the second bonding layer 12ba may be pressed at a temperature of less than 300° C. and bonded to each other to form the bonding layer 12a, thereby bonding the first growth substrate 11aa and the second growth substrate 11ba.

It is preferable that the bonding layer 12a be formed of a material that does not melt or decompose around a growth temperature of a light-emitting portion 110a, which is a Group III nitride semiconductor layer, and simultaneously does not cause issues such as contamination during a growth process. Specifically, a dielectric material, of which physical properties do not change in a metalorganic chemical vapor deposition (MOCVD) chamber (with a temperature of 1,000° C. or more and a reducing atmosphere) in which Group III nitride semiconductors are grown, is preferentially selected as a material for forming the bonding layer 12a. For example, the material for forming the bonding layer 12a may include silicon oxide (SiO₂, 0.8 ppm), silicon nitride (SiNₓ, 3.8 ppm), silicon carbon nitride (SiCN, 3.8 ppm to 4.8 ppm), aluminum nitride (AlN, 4.6 ppm), or aluminum oxide (Al2O3, 6.8 ppm) and may further include flowable oxides (FOₓ) such as spin-on-glass (SOG, liquid SiO₂) or hydrogen silsesquioxane (HSQ) to improve surface roughness.

In addition, a sacrificial separation layer 13a may be disposed on at least one of the upper surface of the first growth substrate 11aa and the lower surface of the second growth substrate 11ba.

That is, the sacrificial separation layer 13a may be disposed on an upper surface, a lower surface, or both the upper surface and lower surface of the bonding layer 12a. In this case, in the bonding operation S120a, the sacrificial separation layer 13a may be formed on the upper surface of the first growth substrate 11aa to form the first bonding layer 12aa on an upper surface of the sacrificial separation layer 13a, the sacrificial separation layer 13a may be formed on the lower surface of the second growth substrate 11ba to form the second bonding layer 12ba on a lower surface of the sacrificial separation layer 13a, and then the first bonding layer 12aa and the second bonding layer 12ba may be bonded to each other to form the bonding layer 12a, thereby bonding the first growth substrate 11aa and the second growth substrate 11ba. However, of course, the sacrificial separation layer 13a may be omitted when a growth substrate may be separated through the bonding layer 12a.

Here, the sacrificial separation layer 13a is a layer that is sacrificed and separated when the growth substrate is separated using an LLO or chemical lift-off (CLO) technique. It is preferable to use the LLO technique, and it is preferable that the sacrificial separation layer 13a be formed of a material that does not melt or decompose around the growth temperature of the light-emitting portion 110a, which is a Group III nitride semiconductor layer, and simultaneously does not cause issues such as contamination during a growth process.

Meanwhile, when the LLO technique is used to separate the growth substrate, the sacrificial separation layer 13a is formed of a material that may be sacrificed and separated through a thermochemical decomposition reaction. For example, in the case of a sapphire growth substrate, the sacrificial separation layer 13a may be formed of a Group III nitride semiconductor material such as gallium nitride (GaN), indium gallium nitride (InGaN), aluminum gallium nitride (AlGaN), or indium aluminum nitride (InAlN).

In addition, when the CLO technique is used to separate the growth substrate, the sacrificial separation layer 13a may be formed of a material including chromium nitride (CrN), titanium nitride (TiN), or the like which may be wet-etched.

The forming operation S130a is an operation of manufacturing a template by forming the second growth substrate 11ba into an ultra-thin type such that the second growth substrate 11ba functions as a semiconductor seed layer.

In this case, it is preferable that the formed sapphire second growth substrate 11ba be formed to have a thickness of less than 50 μm to enable the manufacture of a small die (epitaxy die or chip) with a thickness of less than 50 μm, which has been previously impossible to manufacture.

Here, the second growth substrate 11ba may be formed through a sapphire substrate polishing process to be described below. In this case, a final thickness F to be formed may be calculated as follows through a thickness A of the first growth substrate 11a, a thickness B of the second growth substrate 11ba, the total thickness C of bonded substrates prior to polishing formation, and a target thickness D of the second growth substrate 11ba.
i) The thickness B of the second growth substrate 11ba−the target thickness D of the second growth substrate 11ba=a thickness E of the sapphire substrate to be removed through polishing.
ii) The total thickness C of bonded substrates prior to polishing formation−the thickness E of the sapphire substrate to be removed through polishing=a final thickness F of the second growth substrate 11ba after polishing.

In addition, a specific process is as follows, but the present invention is not limited thereto, and a process is not limited as long as the process is for forming the second growth substrate 11ba to the final thickness F. First, a lapping process of mechanically polishing sapphire of the second growth substrate 11ba at a high speed is performed, and then a mechanical polishing process is performed such that the second growth substrate 11ba has an accurate ultra-thin final thickness F. Thereafter, in order to enable the epitaxy growth of a Group III nitride semiconductor, as a final forming operation, a chemical mechanical polishing (CMP) process is performed such that a surface of the second growth substrate 11ba has a surface roughness of 0.5 nm or less, thereby completing a forming process.

In addition, if necessary, in order to improve the quality of a Group III nitride semiconductor epitaxy thin film and maximize light extraction efficiency after the completion of the CMP process, it is also preferable that the second growth substrate 11ba have a protrusion shape that is patterned regularly or irregularly in various dimensions (sizes and shapes) in microscale or nanoscale on an upper surface of the sapphire.

As a smaller compact die (epitaxy die or chip) is required for manufacturing a mini- or micro-level semiconductor light-emitting device, a thinner-sapphire process technology is required.

In this case, when a sapphire growth substrate was thinly formed from the beginning and then a Group III nitride semiconductor was grown, a problem occurred in which a die or wafer was deformed and damaged during a forming or transferring process due to thermo-mechanical induced stress caused by differences in lattice constant (LC) and coefficient of thermal expansion (CTE) between the sapphire growth substrate and the Group III nitride semiconductor.

Accordingly, in the present invention, an ultra-thin type sapphire substrate (second growth substrate 11ba) is used as a seed layer, and a relatively thick carrier sapphire substrate (first growth substrate 11aa) is bonded to a lower portion thereof, thereby solving the problem of damage to a wafer due to thermo-mechanical induced stress caused by differences in LC and CTE between the thin sapphire growth substrate and the Group III nitride semiconductor. After a structure of a semiconductor light-emitting device is completed on such a template, the thick first growth substrate 11aa is removed in a final process, thereby enabling the manufacturing of a small die (epitaxy die or chip) having a thickness of less than 50 μm.

The device forming operation S140a is an operation of forming a semiconductor light-emitting device structure on the second growth substrate 11ba of the manufactured template. However, the present invention is not limited thereto, and it will be apparent to those skilled in the art that the template may be applied to a switching or wireless amplifier power semiconductor device such as a high electron mobility transistor (HEMT) or an AlN-based communication filter.

As shown in FIGS. 2 and 4, the device forming operation S140a includes, more specifically, a first operation S141a, a second operation S142a, a third operation S143a, and a fourth operation S144a.

The first operation S141a is an operation of growing the light-emitting portion 110a on the second growth substrate 11ba formed into an ultra-thin type of a semiconductor growth template. The relatively thick carrier sapphire substrate (first growth substrate 11aa) is bonded at a lower portion of the semiconductor growth template of the present invention.

Here, the light-emitting portion 110a generates light, and when the light-emitting portion 110a emits ultraviolet light, blue light, green light, red light, or the like, binary, ternary, and quaternary compounds of Group III (Al, Ga, and In) nitride semiconductors such as indium nitride (InN), indium gallium nitride (InGaN), gallium nitride (GaN), aluminum gallium nitride (AlGaN), aluminum nitride (AlN), and aluminum gallium indium nitride (AlGaInN) may be disposed at an appropriate position and order on the second growth substrate 11ba and epitaxially grown.

Furthermore, a Group III nitride semiconductor including scandium (Sc) at a doping or alloy level may also be epitaxially grown and used for a switching or wireless amplifier power semiconductor device such as an HEMT or an AlN-based communication filter.

In particular, in order to emit blue light or green light, a high quality Group III nitride semiconductor of indium gallium nitride (InGaN) having a high indium (In) composition should be preferentially formed on the Group III nitride semiconductor formed of gallium nitride (GaN), aluminum gallium nitride (AlGaN), aluminum nitride (AlN), or aluminum gallium indium nitride (AlGaInN), but the present invention is not limited thereto.

The light-emitting portion 110a may include, more specifically, a first semiconductor region 111a (for example, a p-type semiconductor region), an active region 113a (for example, a multi-quantum well (MQW)), and a second semiconductor region 112a (for example, an n-type semiconductor region). The light-emitting portion 110a may have a structure in which the second semiconductor region 112a, the active region 113a, and the first semiconductor region 111a are sequentially epitaxially grown on the second growth substrate 11ba and may typically have an overall thickness of about 5.0 μm to about 8.0 μm by ultimately including a plurality of layers of Group III nitrides, but the present invention is not limited thereto.

Each of the first semiconductor region 111a, the active region 113a, and the second semiconductor region 112a may be provided as a single layer or multiple layers, and although not shown, before the light-emitting portion 110a is epitaxially grow on the sapphire second growth substrate 11ba, layers such as a buffer region may be added to improve the quality of the epitaxially grown light-emitting portion 110a. For example, the buffer region may typically have a thickness of about 4.0 μm by including a compliant layer consisting of a nucleation layer and an un-doped semiconductor region to relieve stress and improve thin film quality.

The second semiconductor region 112a has second conductivity (n-type) and is formed on the second growth substrate 11ba. The second semiconductor region 112a may have a thickness of 2.0 μm to 3.5 μm.

The active region 113a generates light using the recombination of electrons and holes and is formed on the second semiconductor region 112a. The active region 113a may be provided as a plurality of layers and have a thickness of several tens nm.

The first semiconductor region 111a has first conductivity (p-type) and is formed on the active region 113a. This first semiconductor region 111a may be provided as a plurality of layers and have a thickness of several tens nm to several μm, and an upper surface thereof has a polarity of a Group 3 device (such as Ga).

That is, the active region 113a is interposed between the first semiconductor region 111a and the second semiconductor region 112a so that holes in the first semiconductor region 111a, which is a p-type semiconductor region, recombine with electrons in the second semiconductor region 112a, which is an n-type semiconductor region, in the active region 113a to generate light.

The second operation S142a is an operation of performing a fab process on the grown light-emitting portion 110a and forming the semiconductor light-emitting device structure on the second growth substrate 11ba.

That is, in the second operation S142a, after the light-emitting portion 110a is etched according to a structure of a lateral chip, a flip chip, a vertical chip, or the like (mesa etching or the like), electrodes 120a (ohmic contact electrodes and the like) electrically connected to the light-emitting portion 110a are formed, and a passivation layer 130a covering portions of the light-emitting portion 110a or the electrodes 120a is formed, thereby performing a fab process of forming a plurality of semiconductor light-emitting device structures.

The third operation S143a is an operation of sawing the second growth substrate 11ba to separate the plurality of semiconductor light-emitting devices formed on the second growth substrate 11ba into die units, and separating the bonding layer 12a and the first growth substrate 11aa from the sacrificial separation layer 13a disposed on the lower surface of the second growth substrate 11ba.

Here, the die unit is an epitaxy die or chip unit and is one separated structure which is necessary for emitting light, that is, one separated unit including electrodes such as an anode and a cathode, and a light-emitting portion including a p-type semiconductor region, an active region, and an n-type semiconductor region.

More specifically, the third operation S143a is an operation of dividing the ultra-thin type second growth substrate 11ba according to individual die sizes. The second growth substrate 11b may be divided through a method using a laser beam. Since the second growth substrate 11ba is an ultra-thin type, the second growth substrate 11ba may also be divided through a patterning or plasma etching process, which is advantageous as the size of the required semiconductor light-emitting device decreases.

In addition, in the third operation S143a, the second growth substrate 11ba, which is basically a sapphire seed layer, is sawn and separated. As shown in FIG. 4, it may be separated up to the sacrificial separation layer 13a, and, if necessary, it may be separated up to the surface of the bonding layer 12a or the first growth substrate 11aa.

Thereafter, a carrier tape T is attached to upper portions of the plurality of semiconductor light-emitting devices separated by sawing the second growth substrate 11ba, and then the first growth substrate 11aa, which is a carrier sapphire substrate, and the bonding layer 12a are separated, thereby manufacturing a semiconductor light-emitting device having a thickness of less than 50 μm. The first growth substrate 11aa may be separated using an LLO technique or a CLO technique according to a material of the sacrificial separation layer 13a.

Meanwhile, as shown in FIG. 5, in the case of the method using a laser beam in the third operation S143a, after cracks are generated on a surface of or inside the second growth substrate 11ba through the laser beam, since the first growth substrate 11aa is separated, the generated cracks may propagate, and thus the semiconductor light-emitting device may be sawn and separated into die units.

More specifically, after the fab process in the second operation S142a is completed, when cracks are generated on a surface of or inside each of a plurality of areas of the second growth substrate 11ba to be sawn into die units through a laser beam irradiation process (ablation or stealth) and then the first growth substrate 11aa and the bonding layer 12a are separated through an LLO technique, the cracks generated in the plurality of areas of the ultra-thin type second growth substrate 11ba vertically propagate, and thus the second growth substrate 11ba may be automatically divided into die units. Meanwhile, after the sawing process, chips are completely spaced apart from each other through the expansion of the carrier tape T.

The fourth operation S144a is an operation of optionally removing the sacrificial separation layer 13a disposed on the lower surface of the second growth substrate 11ba or forming a surface roughness pattern on the sacrificial separation layer 13a disposed on the lower surface of the second growth substrate 11ba to form a light extraction structure. Meanwhile, when the removal of the sacrificial separation layer 13a or the formation of a pattern is not necessary, the fourth operation S144a may be omitted.

The sacrificial separation layer 13a of the present invention may be formed of a transparent material, and thus, as shown in FIG. 6, when a surface roughness pattern with a preset shape or an irregular shape is formed on the sacrificial separation layer 13a, light generated in the active region 113a may be extracted into the air as much as possible. This is advantageous in a case in which it is impossible to form a light extraction structure on the ultra-thin type second growth substrate 11ba or the light-emitting portion 110a.

Hereinafter, a method S100b of manufacturing a power semiconductor device using a semiconductor growth template according to a first embodiment of the present invention will be described in detail with reference to the accompanying drawings.

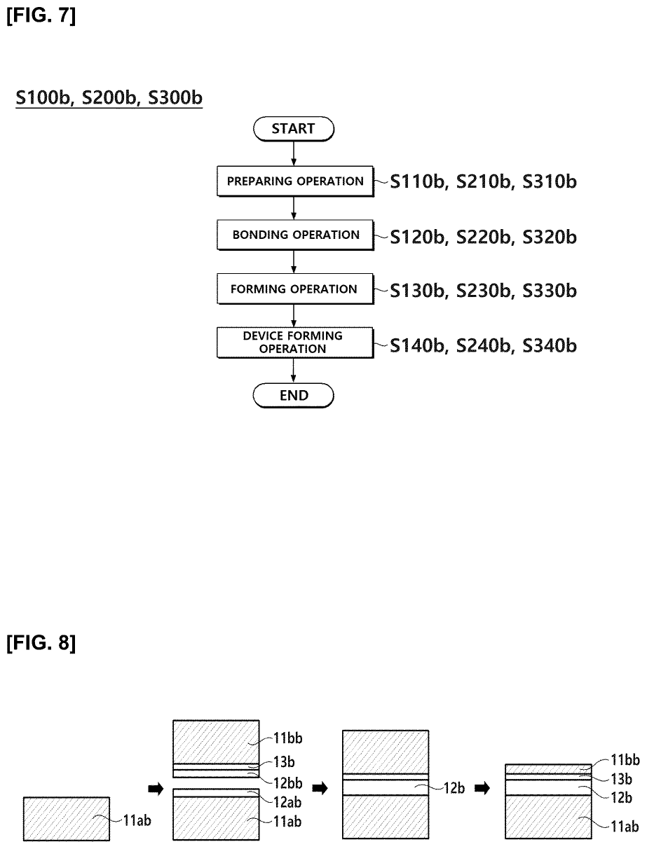

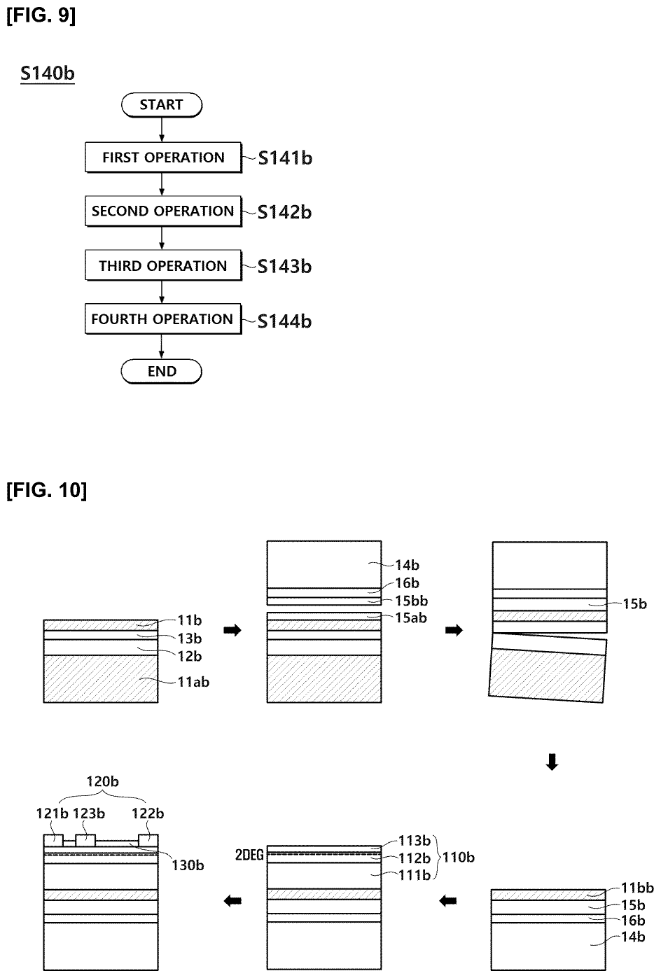

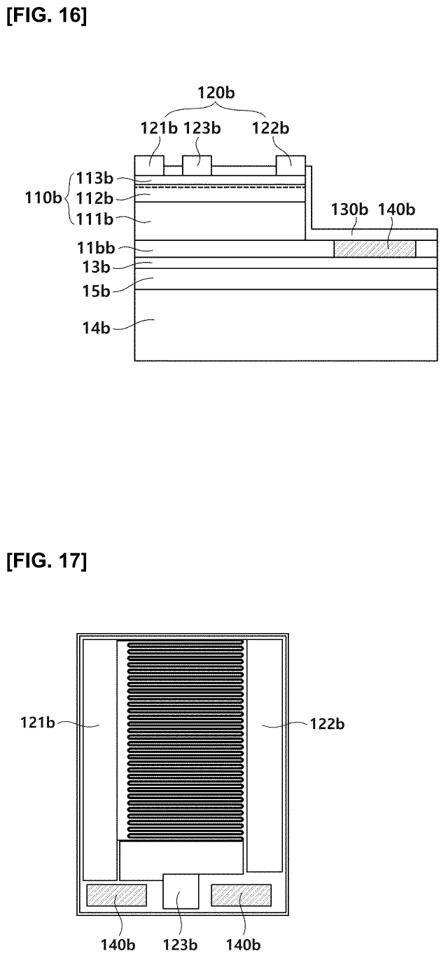

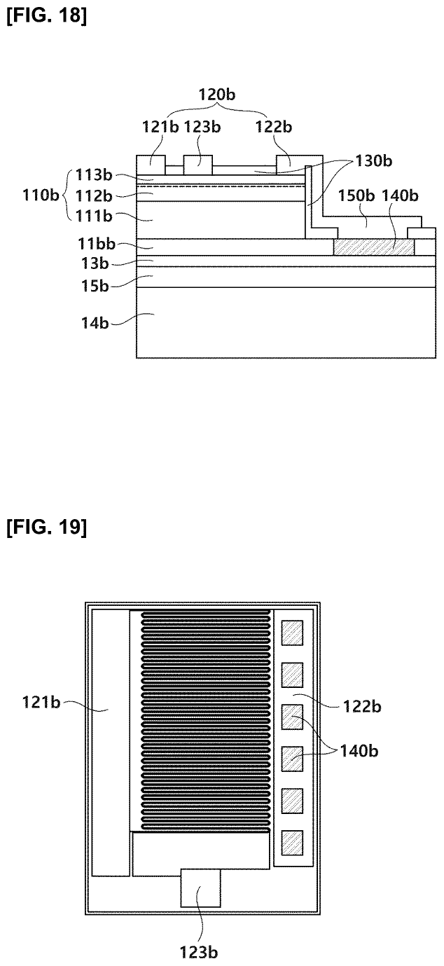

FIG. 7 is a flowchart of a method of manufacturing a power semiconductor device using a semiconductor growth template according to first to third embodiments of the present invention. FIG. 8 illustrates a process of manufacturing a template through the method of manufacturing a power semiconductor device using a semiconductor growth template according to the first to third embodiments of the present invention. FIG. 9 is a flowchart of an device forming operation of the method of manufacturing a power semiconductor device using a semiconductor growth template according to the first embodiment of the present invention. FIG. 10 illustrates a process of forming a power semiconductor device on the template in the method of manufacturing a power semiconductor device using a semiconductor growth template according to the first embodiment of the present invention. FIGS. 16 and 17 illustrate a heat dissipation portion being formed on a second growth substrate in the method of manufacturing a power semiconductor device using a semiconductor growth template according to the first to third embodiments of the present invention. FIGS. 18 and 19 illustrate a heat dissipation portion and a connection portion being formed on the second growth substrate in the method of manufacturing a power semiconductor device using a semiconductor growth template according to the first to third embodiments of the present invention.

As shown in FIGS. 7 and 8, the method S100b of manufacturing a power semiconductor device using a semiconductor growth template according to the first embodiment of the present invention includes a preparing operation S110b, a bonding operation S120b, a forming operation S130b, and an device forming operation S140b.

The preparing operation S110b is an operation of providing a first growth substrate 11ab and a second growth substrate 11bb.

Here, the first growth substrate 11ab and the second growth substrate 11bb may be provided as sapphire substrates. The sapphire substrates are optically transparent and high temperature-heat resistant substrates that may (theoretically) transmit 100% of a laser beam (single wavelength light) without absorption in an LLO process, and may be provided using a-phase Al₂O₃ sapphire (including ScAlMgO₄). In addition, it is preferable that the growth substrate have a protrusion shape that is patterned regularly or irregularly in various dimensions (sizes and shapes) in microscale or nanoscale in order to minimize crystal defects in a Group III nitride semiconductor epitaxy thin film grown thereon.

In addition, as the first growth substrate 11ab serves as a carrier sapphire substrate, although the first growth substrate 11ab does not require relatively high quality as compared to the second growth substrate 11bb, the first growth substrate 11ab is required to be optically transparent by both surfaces being polished.

The second growth substrate 11bb serves as a growth sapphire substrate and is formed into an ultra-thin type in a subsequent operation to serve as a seed layer. The second growth substrate 11bb should be positioned such that a surface on which a Group III nitride semiconductor such as gallium nitride (GaN) is grown becomes an upper surface and is required to be optically transparent by both surfaces being polished to high quality.

The bonding operation S120b is an operation of bonding the first growth substrate 11ab and the second growth substrate 11bb through a bonding layer 12b.

More specifically, the bonding layer 12b may be formed on an upper surface of the first growth substrate 11ab or a lower surface of the second growth substrate 11bb to bond the first growth substrate 11ab and the second growth substrate 11bb. Preferably, after a first bonding layer 12ab is formed on the upper surface of the first growth substrate 11ab and a second bonding layer 12bb is formed on the lower surface of the second growth substrate 11bb, the first bonding layer 12ab and the second bonding layer 12bb may be pressed at a temperature of less than 300° C. and bonded to each other to form the bonding layer 12b, thereby bonding the first growth substrate 11ab and the second growth substrate 11bb.

It is preferable that the bonding layer 12b be formed of a material that does not melt or decompose even at a growth temperature (about 1,000° C.) of a Group III nitride semiconductor layer 110b and simultaneously does not cause issues such as contamination during a growth process. Specifically, a dielectric material, of which physical properties do not change in a MOCVD chamber (with a temperature of about 1,000° C. or more and a reducing atmosphere) in which a Group III nitride semiconductor is grown, is preferentially selected as a material for forming the bonding layer 12b. For example, the material for forming the bonding layer 12b may include silicon oxide (SiO₂, 0.8 ppm), silicon nitride (SiNₓ, 3.8 ppm), silicon carbon nitride (SiCN, 3.8 ppm to 4.8 ppm), aluminum nitride (AlN, 4.6 ppm), or aluminum oxide (Al₂O₃, 6.8 ppm) and may further include a flowable oxide (FOₓ) such as SOG (liquid SiO₂) and hydrogen silsesquioxane (HSQ) for surface improvement.

In addition, a sacrificial separation layer 13b may be disposed on at least one of the upper surface of the first growth substrate 11ab and the lower surface of the second growth substrate 11bb.

That is, the sacrificial separation layer 13b may be disposed on an upper surface, a lower surface, or both the upper surface and lower surface of the bonding layer 12b. In this case, in the bonding operation S120b, the sacrificial separation layer 13b may be formed on the upper surface of the first growth substrate 11ab to form the first bonding layer 12ab on an upper surface of the sacrificial separation layer 13b, the sacrificial separation layer 13b may be formed on the lower surface of the second growth substrate 11bb to form the second bonding layer 12bb on a lower surface of the sacrificial separation layer 13b, and then the first bonding layer 12ab and the second bonding layer 12bb may be bonded to each other to form the bonding layer 12b, thereby bonding the first growth substrate 11ab and the second growth substrate 11bb. However, of course, the sacrificial separation layer 13b may be omitted when a growth substrate may be separated through the bonding layer 12b.

Here, the sacrificial separation layer 13b is a layer that is sacrificed and separated when the growth substrate is separated using an LLO or CLO technique. It is preferable to use the LLO technique, and it is preferable that the sacrificial separation layer 13b be formed of a material that does not melt or decompose around the growth temperature of the Group III nitride semiconductor layer 110b, and simultaneously does not cause issues such as contamination during a growth process.

Meanwhile, when the LLO technique is used to separate the growth substrate, the sacrificial separation layer 13b is formed of a material that may be sacrificed and separated through a thermochemical decomposition reaction. For example, in the case of a sapphire growth substrate, the sacrificial separation layer 13b may be formed of a Group III nitride semiconductor material such as gallium nitride (GaN), indium gallium nitride (InGaN), aluminum gallium nitride (AlGaN), or indium aluminum nitride (InAlN).

In addition, when the CLO technique is used to separate the growth substrate, the sacrificial separation layer 13b may be formed of a material including chromium nitride (CrN), titanium nitride (TiN), or the like which may be wet-etched.

The forming operation S130b is an operation of manufacturing a template by forming the second growth substrate 11bb into an ultra-thin type such that the second growth substrate 11bb functions as a semiconductor seed layer.

In order to improve the heat dissipation performance of a power semiconductor device, when the growth substrate is completely removed and a high heat dissipation support substrate 14b is bonded, there is an advantage in that the heat dissipation performance of the power semiconductor device may be significantly improved. However, during a process of removing the growth substrate and bonding the high heat dissipation support substrate 14b, the long-term reliability of the power semiconductor device may be adversely affected by thermo-mechanical shock or material diffusion.

Accordingly, in the present invention, the Group III nitride semiconductor layer 110b is grown on the template to form a power semiconductor device structure. However, a growth substrate for the template is not completely removed, the ultra-thin type second growth substrate 11bb is left, and the high heat dissipation support substrate 14b is bonded to a lower portion of the second growth substrate 11bb, thereby preventing an adverse effect on the long-term reliability of the power semiconductor device due to thermo-mechanical shock or material diffusion during a process of bonding the high heat dissipation support substrate 14b.

In this case, it is preferable that the formed sapphire second growth substrate 11bb have a thickness of less than 50 μm for heat dissipation of the power semiconductor device.

Meanwhile, the second growth substrate 11bb may be formed through a sapphire substrate polishing process to be described below. In this case, a final thickness F to be formed may be calculated as follows through a thickness A of the first growth substrate 11ab, a thickness B of the second growth substrate 11bb, the total thickness C of bonded substrates prior to polishing formation, and a target thickness D of the second growth substrate 11bb.
i) The thickness B of the second growth substrate 11bb−the target thickness D of the second growth substrate 11bb=a thickness E of the sapphire substrate to be removed through polishing.
ii) The total thickness C of bonded substrates prior to polishing formation−the thickness E of the sapphire substrate to be removed through polishing=a final thickness F of the second growth substrate 11bb after polishing.

In addition, a specific process is as follows, but the present invention is not limited thereto, and a process is not limited as long as the process is for forming the second growth substrate 11bb to the final thickness F. First, a lapping process of mechanically polishing sapphire of the second growth substrate 11bb at a high speed is performed, and then a mechanical polishing process is performed such that the second growth substrate 11bb has an accurate ultra-thin final thickness F. Thereafter, in order to enable the epitaxy growth of a Group III nitride semiconductor, as a final forming operation, a CMP process is performed such that a surface of the second growth substrate 11bb has a surface roughness of 0.5 nm or less, thereby completing a forming process.

In addition, if necessary, in order to improve the quality of a Group III nitride semiconductor epitaxy thin film after the completion of the CMP process, it is also preferable that the second growth substrate 11bb has a protrusion shape that is patterned regularly or irregularly in various dimensions (sizes and shapes) in microscale or nanoscale on an upper surface of the sapphire.

The device forming operation S140b is an operation of forming a power semiconductor device on the second growth substrate 11bb of the manufactured template. In the present embodiment, although an example of an HEMT structure has been described, the present invention is not limited thereto, and the template of the present invention may also be applied to a power semiconductor device for a switching or wireless amplifier, such as a metal oxide semiconductor field effect transistor (MOSFET) or a junction field effect transistor (JFET), a semiconductor light-emitting device such as mini-light-emitting diode (LED) or a micro-LED, or an AlN-based communication filter.

As shown in FIGS. 9 and 10, the device forming operation S140b includes, more specifically, a first operation S141b, a second operation S142b, a third operation S143b, and a fourth operation S144b.

The first operation S141b is an operation of bonding the second growth substrate 11bb formed into the ultra-thin type and a final support substrate 14b through a bonding layer 15b.

Here, as the final support substrate 14b, a substrate that suits the purpose of a power semiconductor device to be manufactured may be selected from silicon carbide (SiC), silicon (Si), and AlN ceramic substrates. Among these, due to a CTE that matches that of an HEMT stack structure, the AlN ceramic substrate may be preferentially selected due to advantages such as an increase in thickness of a stacked structure, an improvement in composition uniformity, high heat dissipation performance, a reduction in costs, and an integrated circuit (IC) processability.

In addition, it is preferable that the bonding layer 15b be formed of a material that does not melt or decompose even at the growth temperature (about 1,000° C.) of the Group III nitride semiconductor layer 110b and simultaneously does not cause issues such as contamination during a growth process. Specifically, a dielectric material, of which physical properties do not change in a MOCVD chamber (with a temperature of 1,000° C. or more and a reducing atmosphere) in which a Group III nitride semiconductor is grown, is preferentially selected as a material for forming the bonding layer 15b. For example, the material for forming the bonding layer 15b may include silicon oxide (SiO₂, 0.8 ppm), silicon nitride (SiNₓ, 3.8 ppm), silicon carbon nitride (SiCN, 3.8 ppm to 4.8 ppm), aluminum nitride (AlN, 4.6 ppm), or aluminum oxide (Al₂O₃, 6.8 ppm) and may further include a flowable oxide (FOₓ) such as SOG (liquid SiO₂) and hydrogen silsesquioxane (HSQ) for surface improvement.

More specifically, the bonding layer 15b may be formed on an upper surface of the second growth substrate 11bb or a lower surface of the final support substrate 14b to bond the second growth substrate 11bb and the final support substrate 14b. Preferably, after a first bonding layer 15ab is formed on the upper surface of the second growth substrate 11bb and a second bonding layer 15bb is formed on the lower surface of the final support substrate 14b, the first bonding layer 15ab and the second bonding layer 15bb may be pressed at a temperature of less than 300° C. and bonded to each other to form the bonding layer 15b, thereby bonding the second growth substrate 11bb and the final support substrate 14b to each other.

Meanwhile, a reinforcement layer that reinforces the bonding strength of the bonding layer 15b and induces compressive stress may be disposed on at least one of upper and lower surfaces of the bonding layer 15b, that is, between the bonding layer 15b and the final support substrate 14b and/or between the bonding layer 15b and the second growth substrate 11bb. A material constituting the reinforcement layer may be selected from materials that do not melt even at the growth temperature (about 1,000° C.) of the Group 3 nitride semiconductor layer 110b and do not cause problems in the growth of the Group 3 nitride semiconductor layer 110b.

Here, the reinforcement layer includes, more specifically, a compressive stress layer disposed on the final support substrate, and a bonding reinforcement layer disposed on the compressive stress layer.

The compressive stress layer is a layer that induces compressive stress and is formed of a dielectric material having a larger value than a CTE of the final support substrate 14b, for example, a material that relieves tensile stress, that is, induces compressive stress, such as aluminum nitride (AlN, 4.6 ppm), aluminum nitride oxide (AlNO, 4.6 ppm to 6.8 ppm), aluminum oxide (Al₂O₃, 6.8 ppm), silicon carbide (SiC, 4.8 ppm), silicon carbide nitride (SiCN, 3.8 ppm to 4.8 ppm), gallium nitride (GaN, 5.6 ppm), or gallium nitride oxide (GaNO, 5.6 ppm to 6.8 ppm). The compressive stress layer serves to improve product quality through stress control.

The bonding reinforcement layer is a layer introduced to reinforce bonding strength when the second growth substrate 11bb is bonded to the final support substrate 14b through the bonding layer 15b. The second bonding layer 15bb is formed on the bonding reinforcement layer, and it is preferable that the material constituting the bonding reinforcement layer be preferentially selected from silicon oxide (SiO₂), silicon nitride (SiNₓ), and the like.

Meanwhile, in the present invention, in some cases, the bonding reinforcement layer or the compressive stress layer may be omitted, and in some cases, both the entire reinforcement layer may be omitted so that the final support substrate 14b and the bonding layer 15b may be in direct contact with each other. In this case, the bonding layer 15b is formed of a material such as silicon (Si) having a larger CTE than the final support substrate 14b, thereby forming a structure that induces compressive stress as well as having a bonding function.

The second operation S142b is an operation of separating the bonding layer 12b and the first growth substrate 11ab from the sacrificial separation layer 13b disposed on the lower surface of the second growth substrate 11bb. Here, the first growth substrate 11ab may be separated using an LLO technique or a CLO technique according to a material of the sacrificial separation layer 13b.

Here, the LLO technique is a technique for irradiating a rear surface of a transparent growth substrate with an ultraviolet (UV) laser beam having a uniform optical power and beam profile, and a single wavelength and separating the growth substrate. In the present embodiment, when the first growth substrate 11ab is separated, the interior of the Group III nitride semiconductor layer 110b bonded to the final support substrate 14b is in a state in which stress is completely relieved and is maintained in a flat state together with the final support substrate 14b. Thereafter, it is preferable that damaged areas, contaminated surface residues, and low-quality single crystal thin film areas according to the separation of the first growth substrate 11ab be removed as completely as possible.

In addition, the CLO technique is a technique for mechanically polishing a rear surface of the first growth substrate 11ab (grinding & polishing) and then completely removing the remaining thin type first growth substrate 11ab using a wet etching method.

Thereafter, the sacrificial separation layer 13b may be optionally removed, and when the sacrificial separation layer 13b is formed of a Group III nitride semiconductor, the sacrificial separation layer 13b may not be removed.

The third operation S143b is an operation of growing the Group III nitride semiconductor layer 110b in a single layer or multiple layers on the sacrificial separation layer 13b or an operation of, when the sacrificial separation layer 13b is removed in the second operation S142b, growing the Group III nitride semiconductor layer 110b in a single layer or multiple layers on the second growth substrate 11bb.

Here, the Group III nitride semiconductor layer 110b may include at least one of a buffer layer 111b, a channel layer 112b, and a barrier layer 113b and may have a structure in which the buffer layer 111b, the channel layer 112b, and the barrier layer 113b are sequentially stacked on the second growth substrate 11bb.

The Group III nitride semiconductor layer 110b may be formed of a single layer or multiple layers of Group III nitride semiconductors and may be formed of gallium nitride (GaN), aluminum gallium nitride (AlGaN), aluminum nitride (AlN), aluminum gallium nitride/gallium nitride (AlGaN/GaN superlattices (SLs)) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), indium aluminum nitride (InAIN), gallium nitride/indium aluminum nitride (GaN/InAlN), aluminum scandium nitride (AlScN), gallium nitride/aluminum scandium nitride (GaN/AlScN), or the like. For the Group III nitride semiconductor layers 110b, a critical quality factor is to reduce the density (≤low 108/cm²) of fatal crystal defects, that is, threading dislocations (present in a direction perpendicular to an initial growth substrate). For example, in the present embodiment, the buffer layer 111b of the Group III nitride semiconductor layer 110b may be formed of gallium nitride (GaN) or aluminum nitride (AlN), the channel layer 112b may be formed of gallium nitride (GaN), and the barrier layer 113b may be formed of aluminum gallium nitride (AlGaN).

The fourth operation S144b is an operation of forming a power semiconductor device on the second growth substrate 11bb by performing a fab process and a chip process on the grown Group III nitride semiconductor layer 110b.

That is, in the fourth operation S144b, if necessary, according to an device structure such as an HEMT, a MOSFET, or a JFET, after the Group III nitride semiconductor layer 110b is etched, a plurality of electrodes 120b (in the case of the HEMT, a source electrode 121b, a drain electrode 122b, a gate electrode 123b, and the like) electrically connected to the Group III nitride semiconductor layer 110b are formed, a fab process and a chip process of forming a passivation layer 130b covering portions of the Group III nitride semiconductor layer 110b or the plurality of electrodes 120b are formed, thereby forming a power semiconductor device structure on the ultra-thin type second growth substrate 11bb.

Meanwhile, as shown in FIGS. 16 and 17, when the final support substrate 14b and the bonding layer 15b each have conductivity (for example, a metallic substrate or metal bonding), in the device forming operation S140b of the present invention (for example, the fourth operation S144b, after forming the power semiconductor device structure, a via hole may be formed in the second growth substrate 11bb, and then a heat dissipation portion 140b may be formed in the via hole.

Specifically, in the fourth operation S144b, after the via hole is formed in an area of the second growth substrate 11bb, on which a power semiconductor device structure is not formed, through laser drilling, the heat dissipation portion 140b may be formed by filling the via hole with a metal material, thereby forming an additional heat dissipation path. Here, the metal material filling the via hole is not limited as long as the material has a heat dissipation function.

In addition, as shown in FIGS. 18 and 19, when a power semiconductor device structure is a vertical structure, in the fourth operation S144b, the electrode 120b generating a high amount of heat among the electrodes 120b of the power semiconductor device may be connected to the heat dissipation portion 140b through a connection portion 150b. For example, in the case of an HEMT structure, the drain electrode 122b may be connected to the heat dissipation portion 140b through the connection portion 150b. That is, the connection portion 150b functions as a drain pad, and a plurality of heat dissipation portions 140b are disposed below the drain pad, thereby obtaining an effect of reducing a chip size and improving heat dissipation performance. Here, a material of the connection portion 150b is not limited as long as the material may transfer heat generated in the drain electrode 122b to the heat dissipation portion 140b, and the connection portion 150b may be formed of the same material as the heat dissipation portion 140b.

Hereinafter, a method S200b of manufacturing a power semiconductor device using a semiconductor growth template according to the second embodiment of the present invention will be described in detail with reference to the accompanying drawings.

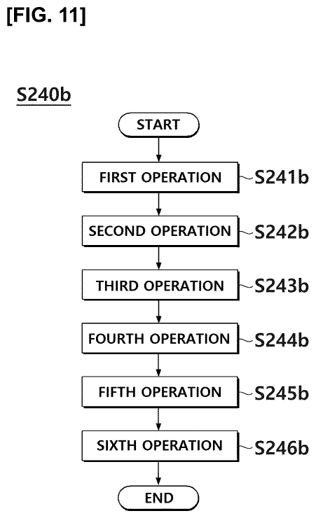

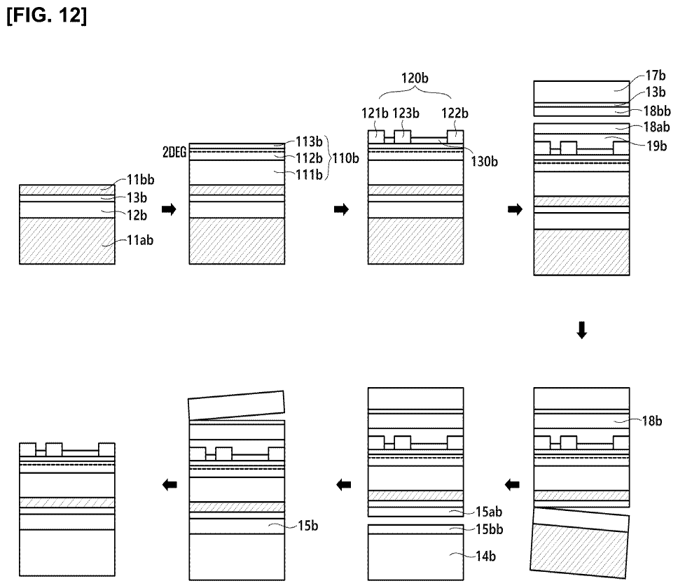

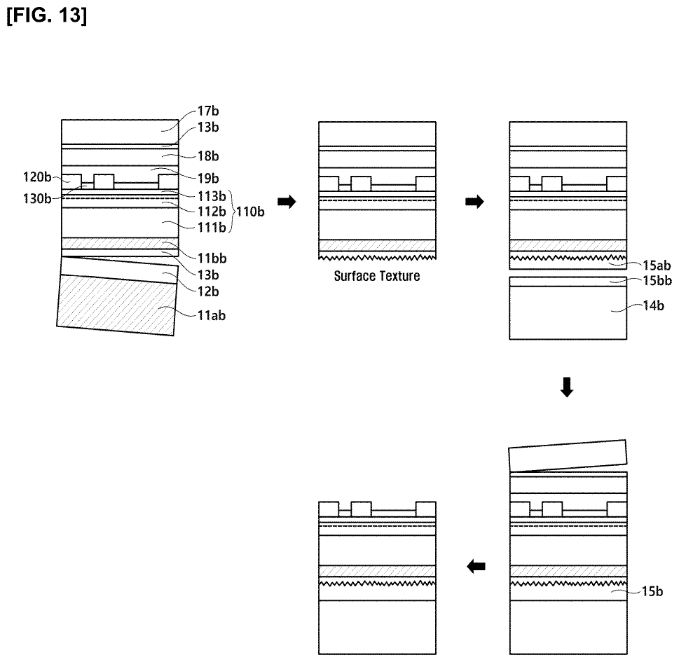

FIG. 7 is a flowchart of the method of manufacturing a power semiconductor device using a semiconductor growth template according to the first to third embodiments of the present invention. FIG. 8 illustrates the process of manufacturing the template through the method of manufacturing a power semiconductor device using a semiconductor growth template according to the first to third embodiments of the present invention. FIG. 11 is a flowchart of the device forming operation of the method of manufacturing a power semiconductor device using a semiconductor growth template according to the second embodiment of the present invention. FIG. 12 illustrates a process of forming a power semiconductor device on the template in the method of manufacturing a power semiconductor device using a semiconductor growth template according to the second embodiment of the present invention. FIG. 13 illustrates a surface roughness pattern being formed on a sacrificial separation layer in the method of manufacturing a power semiconductor device using a semiconductor growth template to the second or third embodiment of the present invention. FIGS. 16 and 17 illustrate the heat dissipation portion being formed on the second growth substrate in the method of manufacturing the power semiconductor device using a semiconductor growth template according to the first to third embodiments of the present invention. FIGS. 18 and 19 illustrate the heat dissipation portion and the connection portion being formed on the second growth substrate in the method of manufacturing a power semiconductor device using a semiconductor growth template according to the first to third embodiments of the present invention.

As shown in FIGS. 7 and 8, the method S200b of manufacturing a power semiconductor device using a semiconductor growth template according to the second embodiment of the present invention includes a preparing operation S210b, a bonding operation S220b, a forming operation S230b, and an device forming operation S240b.

Here, since the contents of the preparing operation S210b the bonding operation S220b, and the forming operation S230b which are for manufacturing a template, are the same as those of the method S100b of manufacturing a power semiconductor device using a semiconductor growth template according to the first embodiment of the present invention, redundant descriptions will be omitted.

The device forming operation S240b is an operation of forming a power semiconductor device on a second growth substrate 11bb of the manufactured template. In the present embodiment, although an example of an HEMT structure is described, the present invention is not limited thereto, and the template of the present invention may also be applied to a power semiconductor device for a switching or wireless amplifier, such as a MOSFET or a JFET, a semiconductor light-emitting device such as a mini LED or a micro-LED, or an AlN-based communication filter.

As shown in FIGS. 11 to 13, the device forming operation S240b includes, more specifically, a first operation S241b, a second operation S242b, a third operation S243b, a fourth operation S244b, a fifth operation S245b, and a sixth operation S246b.

The first operation S241b is an operation of growing the Group III nitride semiconductor layer 110b in a single layer or multiple layers on the second growth substrate 11bb, which is formed into an ultra-thin type, of the template.

Here, the Group III nitride semiconductor layer 110b includes at least one of a buffer layer 111b, a channel layer 112b, and a barrier layer 113b and may have a structure in which the buffer layer 111b, the channel layer 112b, and the barrier layer 113b are sequentially stacked on the second growth substrate 11bb.

The Group III nitride semiconductor layer 110b may be formed of a single layer or multiple layers of Group III nitride semiconductors and may be formed of gallium nitride (GaN), aluminum gallium nitride (AlGaN), aluminum nitride (AlN), aluminum gallium nitride/gallium nitride (AlGaN/GaN SLs) with a superlattice structure, aluminum nitride/gallium nitride (AlN/GaN SLs) with a superlattice structure, aluminum gallium nitride/aluminum nitride (AlGaN/AlN SLs) with a superlattice structure, indium gallium nitride (InGaN), indium aluminum nitride (InAlN), gallium nitride/indium aluminum nitride (GaN/InAlN), aluminum scandium nitride (AlScN), gallium nitride/aluminum scandium nitride (GaN/AlScN), or the like. For the Group III nitride semiconductor layers 110b, a critical quality factor is to reduce the density (≤low 108/cm²) of fatal crystal defects, that is, threading dislocations (present in a direction perpendicular to an initial growth substrate). For example, in the present embodiment, the buffer layer 111b of the Group III nitride semiconductor layer 110b may be formed of gallium nitride (GaN) or aluminum nitride (AlN), the channel layer 112b may be formed of gallium nitride (GaN), and the barrier layer 113b may be formed of aluminum gallium nitride (AlGaN).

The second operation S242b is an operation of forming a power semiconductor device on the second growth substrate 11bb by performing a fab process and a chip process on the Grown Group III nitride semiconductor layer 110b.

That is, in the second operation S242b, if necessary, according to an device structure such as an HEMT, a MOSFET, or a JFET, after the Group III nitride semiconductor layer 110b is etched, a plurality of electrodes 120b (in the case of the HEMT, a source electrode 121b, a drain electrode 122b, a gate electrode 123b, and the like) electrically connected to the Group III nitride semiconductor layer 110b are formed, a fab process and a chip process of forming a passivation layer 130b covering portions of the Group III nitride semiconductor layer 110b or the plurality of electrodes 120b are formed, thereby forming a structure of a power semiconductor device on the ultra-thin type second growth substrate 11bb.

Meanwhile, after the fab process is completed, an area of the second growth substrate 11bb, which is a sapphire seed area, should be separated through a process such as a laser scribing or pattern etching process, and when the area is not separated, an issue of a die being cut due to a material difference may occur when a final substrate is made of metal.

The third operation S243b is an operation of bonding an upper portion of the formed power semiconductor device and an intermediate temporary substrate 17b through an adhesive layer 18b.

Here, the intermediate temporary substrate 17b is formed to have a CTE that is the same as or similar to that of the final support substrate 14b. It is preferable that a CTE difference from the final support substrate 14b does not exceed a maximum difference of 2 ppm. Sapphire is preferred as a material of the intermediate temporary substrate 17b. Silicon carbide or glass with a CTE difference of 2 ppm or less from the support substrate 14b may be included.

In addition, the adhesive layer 18b may be formed of various adhesive materials and may be formed, for example, of a material according to various bonding methods including metallic bonding, adhesive bonding, and direct bonding. Since the intermediate temporary substrate 17b needs to be bonded at a lower temperature as a CTE difference from a material of the first growth substrate 11ab becomes greater, it is preferable that the intermediate temporary substrate 17b is formed of a material that may be bonded at as low a temperature as possible.

In this case, in the third operation S243b, in order to protect the power semiconductor device structure, after a protective layer 19b is formed on the power semiconductor device, the protective layer 19b and the intermediate temporary substrate 17b may be bonded through the adhesive layer 18b.

This protective layer 19b may serve to protect the power semiconductor device when the adhesive layer 18b is removed in a subsequent process and may be included in or removed from the final power semiconductor device structure. When included in the final power semiconductor device structure, the protective layer 19b should be formed of a material that may have high resistance to function as a passivation layer 130b, and when removed, the protective layer 19b should be removed so as not to damage the separately formed passivation layer 130b (that is, should be easy to remove or should have high etching selectivity). Meanwhile, representative materials of the protective layer 19b may include SiO₂, SiNₓ, AlN, and the like, but the present invention is not limited thereto.

More specifically, the adhesive layer 18b may be formed on an upper surface of the protective layer 19b or a lower surface of the intermediate temporary substrate 17b to bond the second growth substrate 11bb and the final support substrate 14b. Preferably, after a first adhesive layer 18ab is formed on the upper surface of the protective layer 19b and a second adhesive layer 18bb is formed on the lower surface of the intermediate temporary substrate 17b, the first adhesive layer 18ab and the second adhesive layer 18bb may be pressed at a temperature of less than 300° C. and bonded to each other to form the adhesive layer 18b thereby bonding the protective layer 19b and the intermediate temporary substrate 17b to each other. In addition, the sacrificial separation layer 13b may be disposed between the intermediate temporary substrate 17b and the adhesive layer 18b.

The fourth operation S244b is an operation of separating the bonding layer 12b and the first growth substrate 11ab from the sacrificial separation layer 13b disposed on a lower surface of the second growth substrate 11bb. Here, the first growth substrate 11ab may be separated using an LLO technique or a CLO technique according to a material of the sacrificial separation layer 13b.

Thereafter, the sacrificial separation layer 13b disposed on the lower surface of the second growth substrate 11bb may be removed for the purpose of improving heat dissipation, and when the sacrificial separation layer 13b does not need to be removed, the sacrificial separation layer 13b may be left and bonded to the final support substrate 14b in a subsequent process.

The fifth operation S245b is an operation of bonding the sacrificial separation layer 13b and the final support substrate 14b through the bonding layer 15b or an operation of, when the sacrificial separation layer 13b is removed in the fourth operation S144b, bonding the second growth substrate 11bb and the final support substrate 14b through the bonding layer 15b.

Here, as the final support substrate 14b, a substrate that suits the purpose of a power semiconductor device to be manufactured may be selected from substrates such as a high heat dissipation ceramic substrate (AlN, SiC, or diamond), a metal substrate (Mo, Cu, MoCu, or CuW), a single crystal substrate (Si or SiC), and a composite substrate (CMC).

In addition, it is preferable that the bonding layer 15b is formed of a material used for metallic bonding (eutectic bonding, diffusion bonding, direct bonding, or the like) for high heat dissipation performance.

More specifically, after the bonding layer 15b is formed on the lower surface of the second growth substrate 11bb (or a lower surface of the sacrificial separation layer 13b) or an upper surface of the final support substrate 14b, the second growth substrate 11bb and the final support substrate 14b may be bonded. Preferably, after the first bonding layer 15ab is formed on the lower surface of the second growth substrate 11bb (or the lower surface of the sacrificial separation layer 13b) and the second bonding layer 15bb is formed on the upper surface of the final support substrate 14b, the first bonding layer 15ab and the second bonding layer 15bb may be pressed at a temperature of less than 300° C. and bonded to each other to form the bonding layer 15b, thereby bonding the second growth substrate 11bb (or the sacrificial separation layer 13b) and the final support substrate 14b to each other.

Meanwhile, as shown in FIG. 13, when the sacrificial separation layer 13b disposed on the lower surface of the second growth substrate 11bb is formed of a Group III nitride such as gallium nitride (GaN), in the fifth operation S245b, a surface texture pattern may be formed on the sacrificial separation layer 13b to expand a bonding area, and then the sacrificial separation layer 13b and the final support substrate 14b may be bonded through the bonding layer 15b.

Meanwhile, a reinforcement layer that reinforces the bonding strength of the bonding layer 15b and induces compressive stress may be disposed on at least one of upper and lower surfaces of the bonding layer 15b, that is, between the bonding layer 15b and the final support substrate 14b and/or between the bonding layer 15b and the second growth substrate 11bb. A material constituting the reinforcement layer may be selected from materials that do not melt even at the growth temperature (about 1,000° C.) of the Group 3 nitride semiconductor layer 110b and do not cause problems in the growth of the Group 3 nitride semiconductor layer 110b.

Here, the reinforcement layer includes, more specifically, a bonding reinforcement layer and a compressive stress layer, and since the following contents are the same as those of the method S100b of manufacturing a power semiconductor device using a semiconductor growth template according to the first embodiment of the present invention described above, redundant descriptions thereof will be omitted.

The sixth operation S246b is an operation of separating the adhesive layer 18b and the intermediate temporary substrate 17b from an upper portion of the power semiconductor device through dry or wet etching and optionally removing the protective layer 19b if necessary.

Meanwhile, as shown in FIGS. 16 to 19, in the device forming operation S240b of the present invention (for example, the sixth operation S246b), the heat dissipation portion 140b may be formed. Since the following contents are the same as those of the method S100b of manufacturing a power semiconductor device using a semiconductor growth template according to the first embodiment of the present invention described above, redundant descriptions thereof will be omitted.

Hereinafter, a method S300b of manufacturing a power semiconductor device using a semiconductor growth template according to the third embodiment of the present invention will be described in detail with reference to the accompanying drawings.

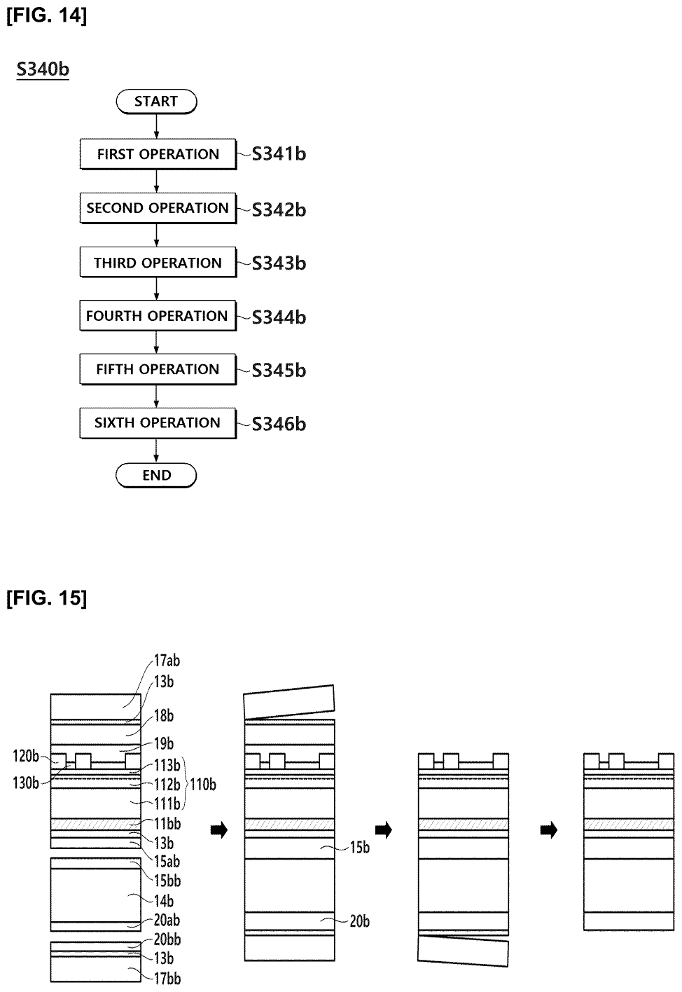

FIG. 7 is a flowchart of the method of manufacturing a power semiconductor device using a semiconductor growth template according to the first to third embodiments of the present invention. FIG. 8 illustrates the process of manufacturing the template through the method of manufacturing a power semiconductor device using a semiconductor growth template according to the first to third embodiments of the present invention. FIG. 13 illustrates the surface roughness pattern being formed on the sacrificial separation layer in the method of manufacturing a power semiconductor device using a semiconductor growth template to the second or third embodiment of the present invention. FIG. 14 is a flowchart of an device forming operation of the method of manufacturing a power semiconductor device using a semiconductor growth template according to the third embodiment of the present invention. FIG. 15 illustrates a process of forming a power semiconductor device on the template in the method of manufacturing a power semiconductor device using a semiconductor growth template according to the third embodiment of the present invention. FIGS. 16 and 17 illustrate the heat dissipation portion being formed on the second growth substrate in the method of manufacturing a power semiconductor device using a semiconductor growth template according to the first to third embodiments of the present invention. FIGS. 18 and 19 illustrate the heat dissipation portion and the connection portion being formed on the second growth substrate in the method of manufacturing a power semiconductor device using a semiconductor growth template according to the first to third embodiments of the present invention.

As shown in FIGS. 7 and 8, the method S300b of manufacturing a power semiconductor device using a semiconductor growth template according to the third embodiment of the present invention includes a preparing operation S310b, a bonding operation S320b, a forming operation S330b, and an device forming operation S340b.

Here, since the contents of the preparing operation S310b of manufacturing a template, the bonding operation S320b, and the forming operation S330b are the same as those of the method S100b of manufacturing a power semiconductor device using a semiconductor growth template according to the first embodiment of the present invention, redundant descriptions will be omitted.

The device forming operation S340b is an operation of forming a power semiconductor device on the second growth substrate 11bb of the manufactured template. In the present embodiment, although an example of an HEMT structure is described, the present invention is not limited thereto, and the template of the present invention may also be applied to a power semiconductor device for a switching or wireless amplifier, such as a MOSFET or a JFET, a semiconductor light-emitting device such as a mini LED or a micro-LED, or an AlN-based communication filter.

As shown in FIGS. 14 and 15, the device forming operation S340b includes, more specifically, a first operation S341b, a second operation S342b, a third operation S343b, a fourth operation S344b, a fifth operation S345b, and a sixth operation S346b.

Here, since the first operation S341b and the second operation S342b are the same as those of the method S200b of manufacturing a power semiconductor device using a semiconductor growth template according to the second embodiment of the present invention described above, redundant descriptions thereof will be omitted.

The third operation S343b is an operation of bonding an upper portion of a formed power semiconductor device and a first temporary substrate 17ab through an adhesive layer 18b.

Here, the first temporary substrate 17ab is formed to have a CTE that is the same as or similar to that of the final support substrate 14b. It is preferable that a CTE difference from the final support substrate 14b does not exceed a maximum difference of 2 ppm. Sapphire is preferred as a material of the first temporary substrate 17ab. Silicon carbide or glass with a CTE difference of 2 ppm or less from the support substrate 14b may be included.

In addition, the adhesive layer 18b may be formed of various adhesive materials and may be formed, for example, of a material according to various bonding methods including metallic bonding, adhesive bonding, and direct bonding. Since the intermediate temporary substrate 17b needs to be bonded at a lower temperature as a CTE difference from a material of the first growth substrate 11ab becomes greater, it is preferable that the first temporary substrate 17ab is formed of a material that may be bonded at as low a temperature as possible.

In this case, in the third operation S343b, in order to protect the power semiconductor device structure, after the protective layer 19b is formed on the power semiconductor device, the protective layer 19b and the first temporary substrate 17ab may be bonded through the adhesive layer 18b.

The protective layer 19b may serve to protect the power semiconductor device when the adhesive layer 18b is removed in a subsequent process and may be included in or removed from the final power semiconductor device structure. When included in the final power semiconductor device structure, the protective layer 19b should be formed of a material that may have high resistance to function as a passivation layer 130b, and when removed, the protective layer 19b should be removed so as not to damage the separately formed passivation layer 130b (that is, should be easy to remove or should have high etching selectivity). Meanwhile, representative materials of the protective layer 19b may include SiO₂, SiNₓ, AlN, and the like, but the present invention is not limited thereto.

More specifically, the adhesive layer 18b may be formed on an upper surface of the protective layer 19b or a lower surface of the first temporary substrate 17ab to bond the second growth substrate 11bb and the final support substrate 14b. Preferably, after the first adhesive layer 18ab is formed on the upper surface of the protective layer 19b and the second adhesive layer 18bb is formed on the lower surface of the first temporary substrate 17ab, the first adhesive layer 18ab and the second adhesive layer 18bb may be pressed at a temperature of less than 300° C. and bonded to each other to form the adhesive layer 18b thereby bonding the protective layer 19b and the first temporary substrate 17ab to each other. In addition, the sacrificial separation layer 13b may be disposed between the first temporary substrate 17ab and the adhesive layer 18b.

The fourth operation S344b is an operation of separating the bonding layer 12b and the first growth substrate 11ab from the sacrificial separation layer 13b disposed on a lower surface of the second growth substrate 11bb. Here, the first growth substrate 11ab may be separated using an LLO technique or a CLO technique according to a material of the sacrificial separation layer 13b.

Thereafter, the sacrificial separation layer 13b disposed on the lower surface of the second growth substrate 11bb may be removed for the purpose of improving heat dissipation, and when the sacrificial separation layer 13b does not need to be removed, the sacrificial separation layer 13b may be left and bonded to the final support substrate 14b in a subsequent process.

The fifth operation S345b is an operation of bonding the sacrificial separation layer 13b and the final support substrate 14b through the bonding layer 15b or an operation of, when the sacrificial separation layer 13b is removed in the fourth operation S344b, bonding the second growth substrate 11bb and the final support substrate 14b through the bonding layer 15b and simultaneously bonding the final support substrate 14b and a second temporary substrate 17bb through a lower bonding layer 20b.

Here, as the final support substrate 14b, a substrate that suits the purpose of a power semiconductor device to be manufactured may be selected from substrates such as a high heat dissipation ceramic substrate (AlN, SiC, or diamond), a metal substrate (Mo, Cu, MoCu, or CuW), a single crystal substrate (Si or SiC), and a composite substrate (CMC). It is preferable that the second temporary substrate 17bb is formed of the same material as the first temporary substrate 17ab described above.

In addition, it is preferable that the bonding layer 15b and the lower bonding layer 20b are formed of a material used for metallic bonding (eutectic bonding, diffusion bonding, direct bonding, or the like) for high heat dissipation performance.

More specifically, after the first bonding layer 15ab is formed on the lower surface of the second growth substrate 11bb (or a lower surface of the sacrificial separation layer 13b) or an upper surface of the final support substrate 14b, the second growth substrate 11bb and the final support substrate 14b may be bonded. Preferably, after the first bonding layer 15ab is formed on the lower surface of the second growth substrate 11bb (or the lower surface of the sacrificial separation layer 13b) and the second bonding layer 15bb is formed on the upper surface of the final support substrate 14b, the first bonding layer 15ab and the second bonding layer 15bb may be pressed at a temperature of less than 300° C. and bonded to each other to form the bonding layer 15b, thereby bonding the second growth substrate 11bb (or the sacrificial separation layer 13b) and the final support substrate 14b to each other.

In addition, after the lower bonding layer 20b is formed on a lower surface of the final support substrate 14b or an upper surface of the second temporary substrate 17bb, the final support substrate 14b and the second temporary substrate 17bb may be bonded. Preferably, after a first lower bonding layer 20ab is formed on the lower surface of the final support substrate 14b and a second lower bonding layer 20bb is formed on the upper surface of the second temporary substrate 17bb (or the sacrificial separation layer 13b) formed on the upper surface of the second temporary substrate 17bb), the first lower bonding layer 20ab and the second lower bonding layer 20bb may be pressed at a temperature of less than 300° C. and bonded to each other to form the lower bonding layer 20b, thereby bonding the final support substrate 14b and the second temporary substrate 17bb (or the sacrificial separation layer 13b) to each other.

Meanwhile, when the sacrificial separation layer 13b disposed on the lower surface of the second growth substrate 11bb is formed of a Group III nitride such as gallium nitride (GaN), in the fifth operation S345b, a surface texture pattern may be formed on the sacrificial separation layer 13b to expand a bonding area, and then the sacrificial separation layer 13b and the final support substrate 14b may be bonded through the bonding layer 15b.

Meanwhile, a reinforcement layer that reinforces the bonding strength of the bonding layer 15b and induces compressive stress may be disposed on at least one of upper and lower surfaces of the bonding layer 15b, between the bonding layer 15b and the final support substrate 14b and/or between the bonding layer 15b and the second growth substrate 11bb. A material constituting the reinforcement layer may be selected from materials that do not melt even at a growth temperature (about 1,000° C.) of the Group 3 nitride semiconductor layer 110b and do not cause problems in the growth of the Group 3 nitride semiconductor layer 110b.

Here, the reinforcement layer includes, more specifically, a bonding reinforcement layer and a compressive stress layer, and since the following contents are the same as those of the method S100b of manufacturing a power semiconductor device using a semiconductor growth template according to the first embodiment of the present invention described above, redundant descriptions thereof will be omitted.

The sixth operation S346b is an operation of separating the adhesive layer 18b and the first temporary substrate 17ab from an upper portion of the power semiconductor device through dry or wet etching, separating the second temporary substrate 17bb from the lower bonding layer 20b, and then optionally removing the protective layer 19b if necessary. In this case, it is preferable that the sacrificial separation layer 13b on a lower surface of the lower bonding layer 20b is removed, and when formed of a conductive metallic bonding material, the lower bonding layer 20b on the lower surface of the final support substrate 14b may not be removed and function as a bonding pad.

Meanwhile, as shown in FIGS. 16 to 19, in the device forming operation S340b of the present invention (for example, the sixth operation S346b), the heat dissipation portion 140b may be formed. Since the following contents are the same as those of the method S100b of manufacturing a power semiconductor device using a semiconductor growth template according to the first embodiment of the present invention described above, redundant descriptions thereof will be omitted.

As described above, although all the components constituting embodiments disclosed herein were described as being combined or combined to operate as one, the present invention is not necessarily limited to these embodiments. That is, one or more of all the components may be selectively combined to operate as one without departing from the scope of the purpose of the present invention.

In addition, the terms “include,” “consist,” or “have” as described above mean that a corresponding component may be intrinsic, unless specifically stated otherwise, and it should interpreted as including other components rather than excluding other components. All terms including technical or scientific terms have the same meanings as those commonly understood by those skilled in the art to which the present invention pertains, unless defined otherwise. Commonly used terms, such as terms defined in a dictionary, should be interpreted as being consistent with the contextual meaning of the related art and are not interpreted in an ideal or excessively formal meaning unless explicitly defined herein.

The above description is merely illustrative of the technical idea of the present invention, and those skilled in the art to which the present invention pertains may make various modifications and variations without departing from the essential characteristics of the present invention.

Accordingly, the embodiments disclosed in the present invention are not intended to limit the technical idea of the present invention, but are for illustrative purposes, and the scope of the technical idea of the present invention is not limited by these embodiments. The spirit and scope of the present invention should be interpreted by the appended claims and encompass all equivalents falling within the scope of the appended claims.

1. A method of manufacturing a semiconductor light-emitting device using a semiconductor growth template, the method comprising:
a preparing operation of preparing a first growth substrate and a second growth substrate;
a bonding operation of bonding the first growth substrate and the second growth substrate through a bonding layer;
a forming operation of forming the second growth substrate into an ultra-thin type with a preset thickness such that the second growth substrate functions as a seed layer and manufacturing a template; and
an device forming operation of forming a semiconductor light-emitting device on the second growth substrate of the template,
wherein the first growth substrate and the second growth substrate are sapphire substrates,
wherein a thickness of the formed second growth substrate is less than 50 μm.

2. (canceled)

3. (canceled)

4. The method of claim 1, wherein a sacrificial separation layer is disposed on at least one of an upper surface of the first growth substrate and a lower surface of the second growth substrate.

5. The method of claim 1, wherein the device forming operation includes:
a first operation of growing a light-emitting portion on the second growth substrate formed into the ultra-thin type;
a second operation of performing a fab process on the grown light-emitting portion and forming the semiconductor light-emitting device on the second growth substrate; and
a third operation of sawing the second growth substrate to divide the semiconductor light-emitting device into die units and separating the bonding layer and the first growth substrate from a sacrificial separation layer disposed on a lower surface of the second growth substrate.

6. The method of claim 5, wherein the device forming operation further includes a fourth operation of removing the sacrificial separation layer disposed on the lower surface of the second growth substrate.

7. The method of claim 5, wherein the device forming operation further includes a fourth operation of forming a surface texture pattern on the sacrificial separation layer disposed on the lower surface of the second growth substrate.

8. The method of claim 5, wherein, in the third operation, a crack is generated on a surface of or inside the second growth substrate through a laser beam and then propagates so that the semiconductor light-emitting device is sawn and divided into the die units.

9. A method of manufacturing a power semiconductor device using a semiconductor growth template, the method comprising:
a preparing operation of preparing a first growth substrate and a second growth substrate;
a bonding operation of bonding the first growth substrate and the second growth substrate through a bonding layer;
a forming operation of forming the second growth substrate into an ultra-thin type with a preset thickness such that the second growth substrate functions as a seed layer and manufacturing a template; and
an device forming operation of forming a power semiconductor device on the second growth substrate of the template,
wherein the first growth substrate and the second growth substrate are sapphire substrates,
wherein a thickness of the formed second growth substrate is less than 50 μm.

10. (canceled)

11. (canceled)

12. The method of claim 9, wherein a sacrificial separation layer is disposed on at least one of an upper surface of the first growth substrate and a lower surface of the second growth substrate.

13. The method of claim 9, wherein, in the device forming operation, the bonding layer and the first growth substrate are separated from the second growth substrate, and the second growth substrate and a support substrate are bonded through the bonding layer.

14. The method of claim 13, a reinforcement layer which reinforces bonding strength of the adhesive layer and induces compressive stress is disposed on at least one of an upper surface and a lower surface of the bonding layer.

15. The method of claim 9, wherein, in the device forming operation, a via hole is formed in the second growth substrate, and then a heat dissipation portion is formed in the via hole.

16. The method of claim 15, wherein the heat dissipation portion is connected to an electrode of the power semiconductor device through a connection portion.

17. The method of claim 9, wherein the device forming operation includes:
a first operation of bonding the second growth substrate, which is formed into the ultra-thin type, and a support substrate through a bonding layer;
a second operation of separating the bonding layer and the first growth substrate from a sacrificial separation layer disposed on a lower surface of the second growth substrate;
a third operation of growing a semiconductor layer on the sacrificial separation layer, or when the sacrificial separation layer is removed, growing the semiconductor layer on the second growth substrate; and
a fourth operation of performing a fab process on the grown semiconductor layer and forming the power semiconductor device on the second growth substrate.

18. The method of claim 9, wherein the device forming operation includes:
a first operation of growing a semiconductor layer on the second growth substrate formed into the ultra-thin type;
a second operation of performing a fab process on the grown semiconductor layer and forming the power semiconductor device on the second growth substrate; and
a third operation of bonding an upper portion of the power semiconductor device and a first temporary substrate through an adhesive layer;
a fourth operation of separating the bonding layer and the first growth substrate from a sacrificial separation layer disposed on a lower surface of the second growth substrate;
a fifth operation of bonding the sacrificial separation layer and a support substrate through a first bonding layer, and
a sixth operation of separating the adhesive layer and the first temporary substrate from an upper portion of the power semiconductor device.

19. The method of claim 18, wherein, in the fifth operation, the sacrificial separation layer and the support substrate are bonded through the bonding layer, and the support substrate and a second temporary substrate are bonded through a lower bonding layer, and
in the sixth operation, the adhesive layer and the first temporary substrate are separated from the upper portion of the power semiconductor device, and then the second temporary substrate is separated from the lower bonding layer.

20. The method of claim 18, wherein, in the third operation, a protective layer is formed on the upper portion of the power semiconductor device, and then the protective layer and the first temporary substrate are bonded through the adhesive layer.

21. The method of claim 18, wherein, in the fifth operation, a surface roughness pattern is formed on the sacrificial separation layer, and then the sacrificial separation layer and the support substrate are bonded through the bonding layer.

22. The method of claim 17, wherein the semiconductor layer includes at least one of a buffer layer, a channel layer, and a barrier layer.
